(19) United States
(12) Patent Application Publication
(10) Pub. No.: US 2009/0067103 A1
(43) Pub. Date: Mar. 12, 2009

(54) SIGNAL CIRCUIT AND INFORMATION PROCESSING APPARATUS HAVING THE SAME

(76) Inventors: Masato Kijima, Oshu (JP); Osamu Hikino, Oshu (JP); Takashi Shiba, Oshu (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/912,517

(22) PCT Filed: Apr. 26, 2006
(86) PCT No.: PCT/JP2006/308709

§ 371 Date: Oct. 25, 2007

(30) Foreign Application Priority Data
Apr. 26, 2005 (JP) 2005-127315

(51) Int. Cl. H02H 9/00; H03H 9/72

(52) U.S. Cl. 361/54; 333/133; 333/101

(57) ABSTRACT

A high-frequency appliance, which is allowed to have an ESD tolerance by using a small-sized and low-cost ESD protection circuit, and in particular, an antenna duplexer having a multi-band high-frequency switch function. There are provided a signal separation unit for separating a first frequency band signal from a second frequency band signal, the second frequency band being lower than the first frequency band, a first SAW filter for inputting the first frequency band signal outputted from the signal separation unit, a second SAW filter for inputting the second frequency band signal outputted from the signal separation unit, and a high-pass filter for permitting passing of the second frequency band signal, and limiting passing of a signal whose frequency band is lower than the second frequency band, the high-pass filter being located on a signal line connecting the signal separation unit and the second SAW filter to each other.

### INCORPORATION BY REFERENCE

The present application claims priority from Japanese Patent Application No. 2005-127315, filed on Apr. 26, 2005, the entire disclosure of which is incorporated herein by reference.

### DETAILED DESCRIPTION OF THE INVENTION

1. Technical Field

The present invention relates to a signal circuit and an information processing apparatus including the same circuit.

2. Background Art

From conventionally, several proposals have been made concerning technologies for preventing breakdown of an internal circuit caused by static electricity which rushes in from an antenna terminal of a mobile wireless appliance.

For example, in Patent Document 1 (JP-A-2003-133989), the technology is disclosed which protects the circuit by inserting a high-pass circuit including an inductor and a capacitor and a resonator including an inductor and a capacitor between a diplexer and the antenna terminal.

Also, in Patent Document 2 (JP-A-2004-72584), the technology is disclosed which protects the circuit by inserting a varistor and an inductor into a signal line between the antenna terminal and a filter.

Also, in Patent Document 3 (JP-A-2004-253948), the technology is disclosed which protects the circuit by inserting a parallel resonance circuit into the signal line between the antenna terminal and the filter.

Patent Document 1: JP-A-2003-133989

Patent Document 2: JP-A-2004-72584

Patent Document 3: JP-A-2004-253948

### DISCLOSURE OF THE INVENTION

### Problem to be solved by the Invention

In order to prevent the electrostatic breakdown that enters from the antenna terminal of a mobile wireless appliance, it is required to attenuate a 0-MHz to 300-MHz band signal. The reason for this requirement is as follows: The electrostatic breakdown which occurs in an actual mobile wireless appliance is mainly attributed to an accidental event that human body in an electrically-charged state comes in contact with the antenna terminal. Moreover, the 0-MHz to 300-MHz frequency component is predominant in the signal waveform generated in this case. The electrostatic breakdown like this seems to be assumed in the above-described Patent Document as well.

In the technology disclosed in the Patent Document 1, however, the configuration presented is as follows: Namely, as illustrated in FIG. 1, the high-pass circuit including the inductor L2 and the capacitor C2 and the resonator including the inductor L3 and the capacitor C3 are inserted between the diplexer and the antenna terminal. When the frequency component causing the electrostatic breakdown is tried to be attenuated using the resonator including the inductor L3 and the capacitor C3, the resonance's degree of acuteness is significantly steep. As a result, it is difficult to uniformly attenuate the 0-MHz to 300-MHz band which should be attenuated. Accordingly, there exists a danger that part of the band may pass the resonator without having been completely attenuated. Also, if the resonance's degree of acuteness is lowered, insertion loss will increase in proximity to a system's pass band, i.e., a 900-MHz band which should be permitted to pass the resonator. Also, values of the inductor and the capacitor, which produce the resonance, become larger at the frequency lower than 300 MHz. As a result, it becomes difficult to achieve built-in implementation of the components into a dielectric substrate. Consequently, there exists a danger that this difficulty may become a hindrance to the small-sized implementation which the mobile wireless appliance is requested to achieve. Furthermore, it is difficult to maintain matching between or among a plurality of bands. For example, in the case of an EGSM and DCS dual-band antenna duplexer, there exists a danger that the insertion loss of the 900-MHz band, which becomes the EGSM band, may increase.

Also, in the technology disclosed in the Patent Document 2, the configuration presented is as follows: Namely, as illustrated in FIG. 2, the varistor and the inductor are inserted into the signal line between the antenna terminal and the filter. In this case, since the varistor is inserted into the circuit, the band is limited into a narrow frequency range in proximity to capacity of the varistor and resonant frequency of the inductor. Accordingly, as is the case with the Patent Document 1, there exists a danger that part of the band may pass the circuit without having been completely attenuated. Also, there exist the other factors, such that the varistor itself is very expensive, and the parallel connection inductor for direct-current leakage is needed together with the varistor. Consequently, there exists a danger that this configuration may become a hindrance to the small-sized implementation and cost reduction.

Also, in the technology disclosed in the Patent Document 3, since the parallel resonance circuit is employed, the pass band by the resonance can not be implemented widely. Accordingly, as is the case with the Patent Documents 1 and 2, there exists a danger that part of the band may pass the circuit without having been completely attenuated. Moreover, it is difficult to attenuate only the 300-MHz or lower band, the attenuation of which is needed for preventing the electrostatic breakdown. Consequently, it is difficult to address multi-band even though it is possible to address the dual-band.

Accordingly, an object of the present invention is to solve the above-described problems, and to provide a high-reliability signal circuit and an information processing apparatus using the same circuit.

### Means for Solving the Problem

In order to solve the above-described problems, in the present invention, there are provided a signal separation unit for separating a first frequency band signal from a second frequency band signal, the second frequency band being lower than the first frequency band, a first SAW filter for inputting the first frequency band signal outputted from the signal separation unit, a second SAW filter for inputting the second frequency band signal outputted from the signal separation unit, and a high-pass filter for permitting passing of the second frequency band signal, and limiting passing of a signal whose frequency band is lower than the second frequency band, the high-pass filter being located on a signal line connecting the signal separation unit and the second SAW filter to each other.

### ADVANTAGES OF THE INVENTION

According to the present invention, it becomes possible to provide a high-reliability signal circuit and an information processing apparatus using the same circuit.

The other objects, features, and advantages of the present invention will become apparent from the following description of embodiments of the present invention associated with the accompanying drawings.

### BEST MODE FOR CARRYING OUT THE INVENTION

As the embodiments of the present invention, in an antenna duplexer having a 0.8-GHz to 2.4-GHz multi-band high-frequency switch function, the explanation will be given below selecting, as an example, a mobile wireless appliance which uses an ESD (: Electrostatic Discharge) protection circuit of composite module on which a surface acoustic wave filter (which, hereinafter, will be referred to as “SAW”) is mounted in particular. As explained earlier, in the mobile wireless appliance, there exists the danger that the internal circuit is broken down by static electricity which rushes in from the antenna terminal. In particular, components used in the antenna duplexer, such as the SAW, a PIN (Positive-Intrinsic-Negative) diode, and a GaAs (Gallium Arsenide) switch, need to be protected by providing the protection circuit against the ESD breakdown.

Hereinafter, using the drawings, the explanation will be given below concerning the embodiments of the present invention. In all of the drawings for explaining the respective embodiments, the same reference notation is allocated to components having the same function. Hereinafter, referring to the drawings, the explanation will be given below regarding the embodiments of the antenna duplexer having the multi-band high-frequency switch function according to the present invention.

FIG. 3 illustrates a block diagram of an EGSM (Extended Global System for Mobile Communications)/DCS (Digital Communication System)-compatible dual-band antenna duplexer according to a first embodiment of the present invention.

In FIG. 3, Ant denotes an antenna terminal, and Dip denotes a diplexer connected to the antenna terminal Ant. The diplexer Dip branches an EGSM 880-MHz to 960-MHz band signal from a DCS 1710-MHz to 1880-MHz band signal, both of which have passed through the antenna terminal Ant. A high-frequency switch SW1 switches the high-frequency side signal branched by the diplexer Dip, i.e., the DCS 1710-MHz to 1880-MHz band signal, to a transmission-side low-pass filter LPF1 and a reception-side filter SAW1. Also, a high-frequency switch SW2 switches the low-frequency side signal branched by the diplexer Dip, i.e., the EGSM 880-MHz to 960-MHz band signal, to a transmission-side low-pass filter LPF2 and a reception-side filter SAW2.

An inductor L4 having 18-nH inductance is connected in parallel to a signal line between the diplexer Dip and the high-frequency switch SW2. The other-end side of this inductor L4 is connected to a GND terminal. Also, a capacitor C4 having 15-pF electrostatic capacitance is connected in series with the signal line between the diplexer Dip and the high-frequency switch SW2, in other words, between the inductor L4 and the high-frequency switch SW2.

By setting the inductance of the inductor L4 at 18 nH or less, it becomes possible to increase the effect of eliminating the static electricity which causes the electrostatic breakdown to occur. Meanwhile, if the value of the inductance is made too small, matching of the signal pass bands collapses, and thus the insertion loss becomes larger. Accordingly, the inductance constant is selected by taking into consideration the level of the electrostatic breakdown to be guaranteed. Also, by setting the electrostatic capacitance of the capacitor C4 at 15 pF or less, it becomes possible to increase the effect of eliminating the static electricity which causes the electrostatic breakdown to occur. From the fact that the inductance of the inductor L4 is equal to 18 nH or less, the electrostatic capacitance constant of the capacitor C4 is selected so as to configure a high-pass filter for attenuating the 0-MHz to 300-MHz band signal, i.e., the frequency component of the static electricity which causes the electrostatic breakdown to occur. Meanwhile, if the electrostatic capacitance of the capacitor C4 is made too small, the insertion loss of the signal pass bands becomes larger. Accordingly, the electrostatic capacitance constant is selected by taking into consideration the level of the electrostatic breakdown to be guaranteed. Also, the inductor L4 and the capacitor C4 function as a protection circuit against the static electricity, and simultaneously implement the matching of the signal pass bands. Consequently, the constants which allow implementation of the matching are selected in order to ensure the level of the electrostatic breakdown to be guaranteed, and in order to suppress the insertion loss down to the lowest possible degree.

The employment of the configuration like this allows the 0-MHz to 300-MHz band signal to be sufficiently attenuated, and allows degradation in the insertion loss to be controlled within 0.05 dB. This condition makes it possible to ensure the ESD tolerance which is adequate as the antenna duplexer. Also, it is possible to attenuate only the 300-MHz or lower band, the attenuation of which is needed for preventing the electrostatic breakdown. Consequently, it is possible to address not only the dual-band, but also multi-band larger than triple-band.

Incidentally, the SAW1 does not necessitate the protection circuit, since the 0-MHz to 300-MHz band signal is suppressed sufficiently in the diplexer. This is because the signal which has passed through a high-pass filter in the diplexer is inputted into the SAW1, and because the 0-MHz to 300-MHz band signal is inputted therein in a state of being attenuated. On the other hand, the signal which has passed through a low-pass filter in the diplexer is inputted into the SAW2, and the 0-MHz to 300-MHz band signal is not attenuated. Accordingly, it is necessary to insert the protection circuit as described above.

FIG. 4 illustrates a block diagram of an EGSM/DCS-compatible dual-band antenna duplexer according to a second embodiment of the present invention. The circuit structure in the second embodiment of the present invention has the same circuit structure as in the first embodiment of the present invention except that an inductor L5 is added between the SW2 and the LPF2. Here, if the inductance of the inductor L5 is set at 39 nH or less, SW2-side impedance of a circuit including the inductor L5 and the LPF2 becomes lower than 50Ω in the 900-MHz band, i.e., the EGSM transmission band. The employment of the structure like this makes it possible to prevent the static electricity, which is applied by the Ant, from flowing into the SAW2, thereby allowing the static electricity to be guided onto the LPF2 side. Here, the SAW2 is exceedingly likely to be broken down by the static electricity; whereas the LPF2 is comparatively resistant to the static electricity. The present configuration makes it possible to acquire the ESD tolerance which is even higher than the one in the first embodiment of the present invention.

FIG. 5 illustrates a block diagram of an EGSM/DCS-compatible dual-band antenna duplexer according to a third embodiment of the present invention. The circuit structure in the third embodiment of the present invention has the same circuit structure as in the first embodiment of the present invention except that an inductor L6 and a capacitor C5 are added between the SAW2 and the SW2. The inductor L6 has 6-nH to 12-nH inductance. The capacitor C5 is added in order to implement the matching of the SAW2, and has substantially 2-pF to 4-pF capacitance. The present inductor L6 causes the static electricity to bypass to a GND, thereby making it possible to enhance the ESD protection effect even further. Also, the capacitor C5 is capable of implementing the optimum matching of the SAW2, which allows prevention of loss degeneration of EGSM Rx. Also, the inductor L6 and the capacitor C5 are small in constants, and thus can be easily built-in inside a multilayered substrate. Accordingly, it becomes possible to suppress a rise in the size or cost.

FIG. 6 illustrates a block diagram of an EGSM/DCS-compatible dual-band antenna duplexer according to a fourth embodiment of the present invention. The circuit structure in the fourth embodiment of the present invention has the same circuit structure as in the first embodiment of the present invention except the following point: The inductor L6 having the 6-nH to 12-nH constant and the capacitor C5 having the substantially 2-pF to 4-pF capacitance are added between the SAW2 and the SW2, and the inductor L5 having the 39-nH or less constant is added between the SW2 and the LPF2. Namely, the present embodiment is a combination of the second embodiment of the present invention and the third embodiment of the present invention. According to the present embodiment, it becomes possible to prevent the static electricity, which is applied by the Ant, from flowing into the SAW2, thereby allowing the static electricity to be guided onto the LPF2 side. Here, the SAW2 is exceedingly likely to be broken down by the static electricity; whereas the LPF2 is comparatively resistant to the static electricity. Simultaneously, the inductor L6 causes the static electricity to bypass to the GND, thereby making it possible to enhance the ESD protection effect even further. Also, the capacitor C5 is capable of implementing the optimum matching of the SAW2, which allows prevention of the loss degeneration of the EGSM Rx. On account of this, it becomes possible to acquire the even higher ESD tolerance.

FIG. 7 illustrates a block diagram of an EGSM/DCS-compatible dual-band antenna duplexer according to a fifth embodiment of the present invention. The circuit structure in the fifth embodiment of the present invention has the same circuit structure as in the fourth embodiment of the present invention except that a capacitor C6 having a 47-pF or less constant is added between the SW2 and the SAW2. According to the present embodiment, the impedance of the low-pass filter LPF2 seen from the Ant side becomes lower than 50Ω because of the inductor L5. As a result, it becomes possible to prevent the static electricity, which is applied by the Ant, from flowing into the SAW2, thereby allowing the static electricity to be guided onto the LPF2 side. Here, the SAW2 is exceedingly likely to be broken down by the static electricity; whereas the LPF2 is comparatively resistant to the static electricity. Simultaneously, the inductor L6 causes the static electricity to bypass to the GND, and the inductor L6 and the capacitor C6 configure a high-pass filter for suppressing the low-frequency band. Consequently, it becomes possible to enhance the ESD protection effect even further. Also, the capacitor C5 is capable of implementing the optimum matching of the SAW2, which allows prevention of the loss degeneration of the EGSM Rx. On account of this, it becomes possible to acquire the even higher ESD tolerance. Namely, it turns out that not only the high-pass filter is inserted into the signal line between the diplexer and the high-frequency switch SW2, but also the high-pass filter is inserted into the signal line between the high-frequency switch SW2 and the SAW2 as well. This situation makes it possible to enhance the ESD tolerance tremendously. Incidentally, from the viewpoint of the low-cost implementation and small-sized implementation, it is also preferable to employ a configuration where the high-pass filter is inserted into only the signal line between the high-frequency switch SW2 and the SAW2 without inserting the high-pass filter into the signal line between the diplexer and the high-frequency switch SW2.

FIG. 8 illustrates a block diagram of an EGSM/DCS-compatible dual-band antenna duplexer according to a sixth embodiment of the present invention. In the present embodiment, the high-frequency switch circuits are replaced by GaAs switches, i.e., semiconductor switches. As is the case with the SAWs, the GaAs switches also have only the weak ESD tolerance. In the present embodiment, as a first ESD protection circuit for the GaAs switch GaAs2, the inductor L4 and the capacitor C4, which configure the high-pass filter for suppressing the 0-MHz to 300-MHz low-frequency band, are added between the Ant and the GaAs switch GaAs1. The present first circuit allows implementation of the ESD protection of the GaAs2. Part of the static electricity, however, passes through the GaAs2, eventually reaching the SAW2. In the present embodiment, as a second ESD protection circuit, the inductor L6 and the capacitor C5 are provided between the GaAs2 and the SAW2. The present circuit configuration, which is a circuit configuration similar to the third embodiment of the present invention, enhances the ESD protection effect even further. On the other hand, the GaAs1 does not necessitate the protection circuit, since the 0-MHz to 300-MHz band is suppressed sufficiently in the diplexer Dip.

Incidentally, in the present embodiment, the GaAs switches are used as the semiconductor switch elements. The present invention, however, is similarly applicable to the other semiconductor switch elements such as CMOS (Complementary Metal Oxide Semiconductor) switches and HEMT (High Electron Mobility Transistor) switches, or to switches using MEMS (Micro Electro Mechanical Systems) or the like. Also, if the ESD tolerance required is ensured by the first ESD protection circuit including the inductor L4 and the capacitor C4, the second ESD protection circuit including the inductor L6 and the capacitor C5 can be eliminated.

FIG. 9 is a diagram for schematically illustrating structure of an antenna duplexer according to a seventh embodiment of the present invention. In this structure, the ESD protection circuit of the present invention is built-in inside a dielectric substrate together with diplexer, switch circuit, circuit configuring low-pass filter, and part of transmission lines or the like. Meanwhile, PIN diode, SAW, and chip components such as resistor, capacitor, and inductor are implemented on the dielectric substrate.

As illustrated in FIG. 9, reference numeral 1 denotes the dielectric substrate, where respective elements and terminals are connected by alternately multilayering a dielectric layer 2 and an electric-conductor pattern 3. Also, when the dielectric substrate 1 is formed, an inductor is formed inside the dielectric substrate 1 by multilayering the electric-conductor pattern 3 in a spiral-like manner, and a capacitor is formed therein by multilayering the plurality of electric-conductor patterns 3 in a manner of being opposed to each other. Part of the circuit is built-in inside the dielectric substrate 1. Also, a SAW4, a diode 5, and a land electrode for implementing the chip components such as resistor, capacitor, and inductor, and further, a land electrode for mounting thereon a metallic cover 7 covering top surface of the dielectric substrate 1 are formed on the top surface of the dielectric substrate 1 by using the electric-conductor patterns 3. Meanwhile, an antenna terminal, a transmission terminal, high-frequency switches, and a control terminal are formed on the bottom surface of the dielectric substrate 1 by using the electric-conductor patterns 3.

In the ESD protection circuit like this, and a mobile wireless appliance using the ESD protection circuit, the ESD tolerance is high. This feature makes it possible to enhance their reliability.

Incidentally, in the above-described respective embodiments, the explanation has been given selecting the EGSM/DCS-compatible dual-band system as the example. The present invention, however, is not limited thereto, but is also applicable to a triple-band system formed by combining the EGSM/DCS with PCS (Personal Communication Services) or GSM850 (Global System for Mobile Communications 850), or to a quad-band system formed by including all these systems. Furthermore, in an antenna duplexer as well which is formed by combining a plurality of systems such as PDC (Personal Digital Cellular), PHS (Personal Handyphone System), GPS (Global Positioning System), Bluetooth, W-CDMA (Wideband Code Division Multiple Access), and cdma2000, basically the same effect can be obtained by inserting an inductor in parallel between an antenna and a high-frequency switch, and further, by inserting a capacitor in series therebetween as a protection circuit against static electricity which rushes in from the antenna.

Summing up the above-described explanation results in the following description:

The configuration employed in the above-described embodiments is as follows: The inductor is inserted in parallel between the diplexer connected to the antenna terminal and the high-frequency switch connected to the transmission-system low-pass filter and the SAW, and further, the capacitor is inserted in series therebetween.

Based on the configuration like this, on account of the diplexer connected to the antenna terminal and branching the signals whose pass bands are different, and the parallel-connected inductor provided on the low-frequency side branched by the diplexer and becoming the first protection circuit, the direct-current component of the static electricity which causes the electrostatic breakdown to occur is absorbed into the GND. This absorption makes it possible to protect the circuit subsequent to the high-frequency switch. Moreover, the capacitor, which becomes the second protection circuit, is connected in series at the position immediately after the inductor, i.e., the first protection circuit. On account of this series-connected capacitor, the direct-current component of the static electricity which causes the electrostatic breakdown to occur is absorbed more effectively into the inductor, i.e., the first protection circuit. Simultaneously, the high-pass filter is configured, which attenuates the frequency component of the static electricity which causes the electrostatic breakdown to occur. These absorption and attenuation make it possible to protect the circuit subsequent to the high-frequency switch.

Also, in particular, the use of the inductor whose inductance is equal to 18 nH or less makes it possible to protect the circuit with more certainty. Also, in particular, the use of the capacitor whose electrostatic capacitance is equal to 15 pF or less makes it possible to protect the circuit with more certainty. Furthermore, even if the constant of the inductor and that of the capacitor are made small, it is possible to implement the matching by adjusting the impedance of the diplexer on the side onto which the present inductor and capacitor are added. This allows the increase in the insertion loss to be suppressed down to the lowest possible degree. Also, since the constant of the parallel-connected inductor and that of the series-connected capacitor become small, it becomes possible to build-in part and the whole of the circuit inside the multilayered substrate. This allows implementation of fabrication of the small-sized, low-height, and low-cost protection circuit.

As having been explained so far, in the embodiments of the present invention, the ESD which has flown in from the antenna is effectively suppressed by the inductor which is inserted in parallel between the diplexer connected to the antenna terminal and the high-frequency switch connected to the transmission-system low-pass filter and the SAW, and the capacitor which is inserted in series therebetween. This effective suppression allows the breakdown of the elements by the ESD to be avoided with the small-sized and low-cost configuration.

The above-described description has been given in association with the embodiments. It is apparent for those who are skilled in the art, however, that the present invention is not limited thereto, and that a variety of modifications and amendments can also be made within the spirit of the present invention and the scope of the appended claims.

### BRIEF DESCRIPTION OF THE DRAWINGS

FIG. 1 is the configuration of the ESD protection circuit according to the prior art;

FIG. 2 is the configuration of the ESD protection circuit according to the prior art;

FIG. 3 is the configuration of the ESD protection circuit according to the first embodiment of the present invention.

FIG. 4 is the configuration of the ESD protection circuit according to the second embodiment of the present invention.

FIG. 5 is the configuration of the ESD protection circuit according to the third embodiment of the present invention.

FIG. 6 is the configuration of the ESD protection circuit according to the fourth embodiment of the present invention.

FIG. 7 is the configuration of the ESD protection circuit according to the fifth embodiment of the present invention.

FIG. 8 is the configuration of the ESD protection circuit according to the fifth embodiment of the present invention.

FIG. 9 is the structure of the antenna duplexer according to the seventh embodiment of the present invention.

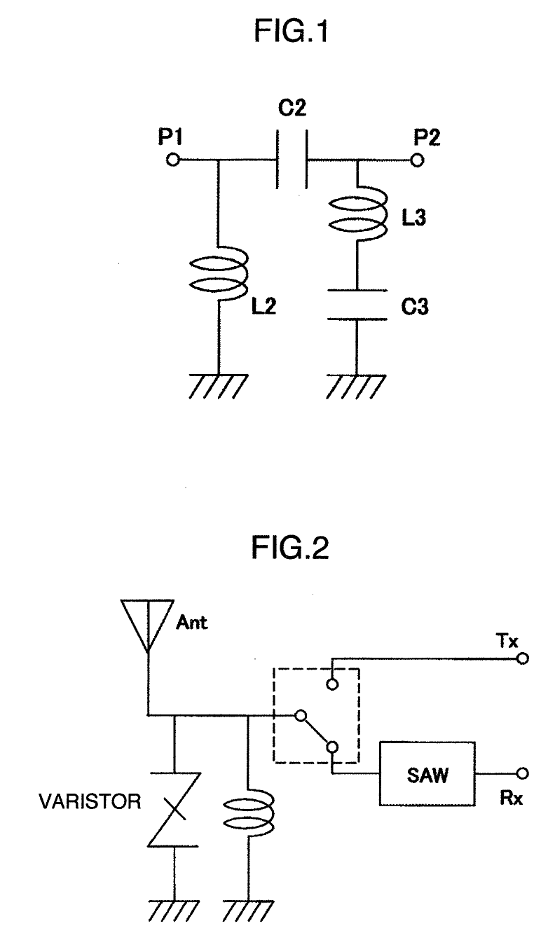

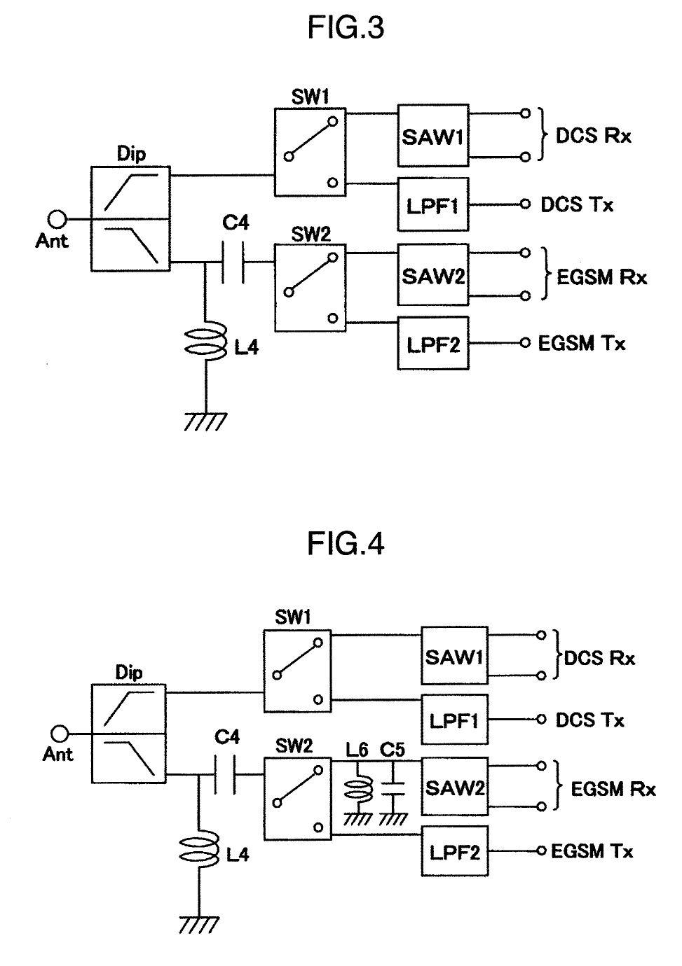

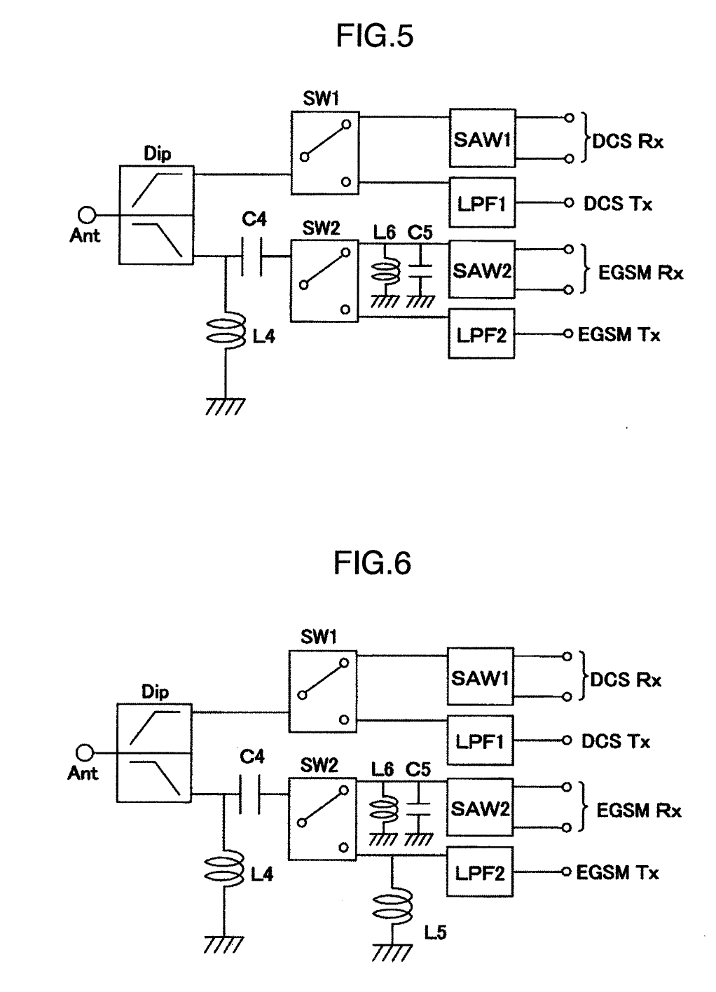

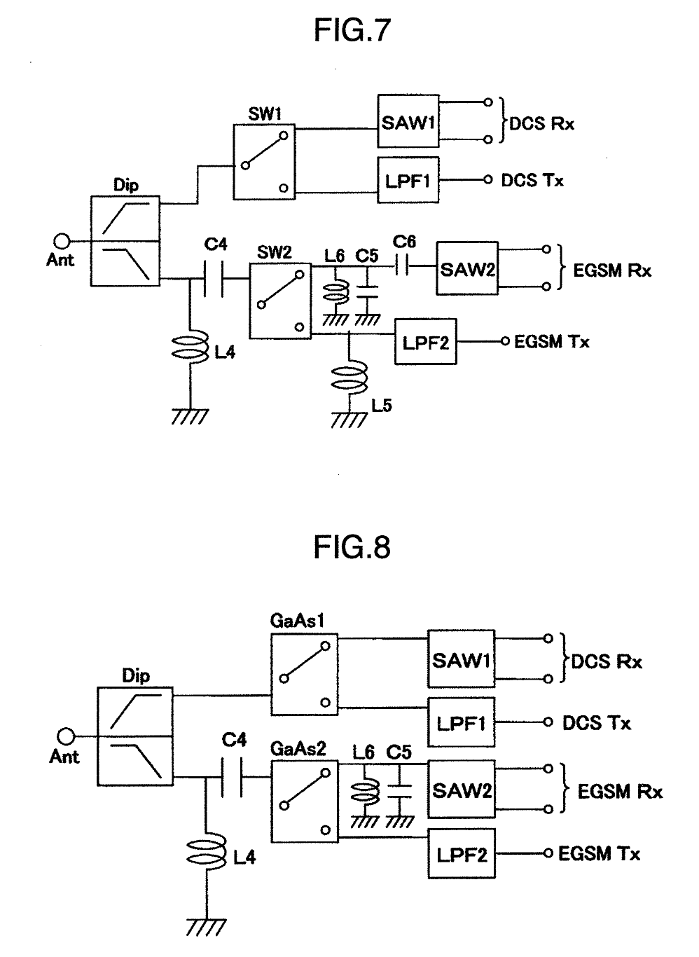

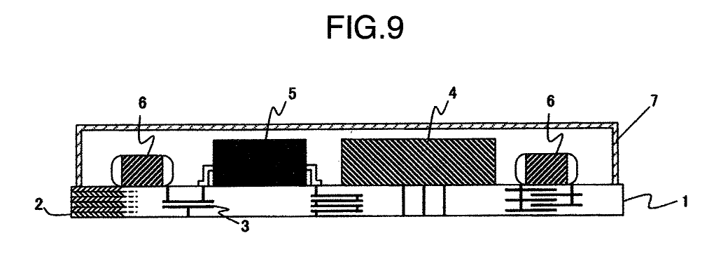

1. A signal circuit, comprising:
a signal separation unit for separating a first frequency band signal from a second frequency band signal, said second frequency band being lower than said first frequency band,
a first SAW filter for inputting said first frequency band signal outputted from said signal separation unit,
a second SAW filter for inputting said second frequency band signal outputted from said signal separation unit, and
a high-pass filter for permitting passing of said second frequency band signal, and limiting passing of a signal whose frequency band is lower than said second frequency band, said high-pass filter being located on a signal line connecting said signal separation unit and said second SAW filter to each other.

2. A signal circuit, comprising:
a signal separation unit for separating a first frequency band signal from a second frequency band signal, said second frequency band being lower than said first frequency band,
a first switching circuit for switching said first frequency band signal between a transmission side and a reception side, said first frequency band signal being outputted from said signal separation unit,
a first SAW filter connected to said reception side of said first switching circuit,
a first low-pass filter connected to said transmission side of said first switching circuit,
a second switching circuit for switching said second frequency band signal between a transmission side and a reception side, said second frequency band signal being outputted from said signal separation unit,
a second SAW filter connected to said reception side of said second switching circuit,
a second low-pass filter connected to said transmission side of said second switching circuit, and
a high-pass filter for permitting passing of said second frequency band signal, and limiting passing of a signal whose frequency band is lower than said second frequency band, wherein
said high-pass filter is located on a signal line connecting said signal separation unit and said second switching circuit to each other.

3. The signal circuit according to claim 1, wherein said high-pass filter operates as a protection circuit for said second SAW filter.

4. The signal circuit according to claim 1, wherein
said high-pass filter comprises a parallel-connected inductor and a series-connected capacitor,
said parallel-connected inductor operating as a first protection circuit for said second SAW filter, said series-connected capacitor being located at a subsequent stage to said parallel-connected inductor for said second SAW filter, and operating as a second protection circuit for said second SAW filter.

5. The signal circuit according to claim 2, wherein a parallel-connected inductor is located between said second switching circuit and said second low-pass filter.

6. The signal circuit according to claim 2, wherein a parallel-connected inductor and a series-connected capacitor are located between said second switching circuit and said second SAW filter.

7. The signal circuit according to claim 2, wherein a parallel-connected inductor, a parallel-connected capacitor, and a series-connected capacitor are located between said second switching circuit and said second SAW filter.

8. A signal circuit, comprising:
a signal separation unit for separating a first frequency band signal, a second frequency band signal, and a third frequency band signal, said second frequency band being lower than said first frequency band, said third frequency band being lower than said second frequency band,
a first SAW filter for inputting said first frequency band signal outputted from said signal separation unit,
a second SAW filter for inputting said second frequency band signal outputted from said signal separation unit,
a third SAW filter for inputting said third frequency band signal outputted from said signal separation unit, and
a high-pass filter for permitting passing of said third frequency band signal, and limiting passing of a signal whose frequency band is lower than said third frequency band, said high-pass filter being located on a signal line connecting said signal separation unit and said third SAW filter to each other.

9. A signal circuit, comprising:
a signal separation unit for separating a first frequency band signal from a second frequency band signal, said second frequency band being lower than said first frequency band, said signal separation unit outputting said first frequency band signal and said second frequency band signal, and
a circuit unit including a parallel-connected inductor and a series-connected capacitor located at a subsequent stage to said parallel-connected inductor, said circuit unit being located on an output side of said second frequency band signal in said signal separation unit.

10. A signal circuit, comprising:
a signal separation unit for separating a first frequency band signal from a second frequency band signal, said second frequency band being lower than said first frequency band, said signal separation unit outputting said first frequency band signal and said second frequency band signal, and
a circuit unit for limiting passing of a signal whose frequency band is lower than said second frequency band, and permitting passing of said second frequency band signal and a signal whose frequency band is higher than said second frequency band, said circuit unit being located on an output side of said second frequency band signal in said signal separation unit.

11. A signal circuit, comprising:
a signal separation unit for separating a first frequency band signal from a second frequency band signal, said second frequency band being lower than said first frequency band,
a first circuit unit for inputting said first frequency band signal outputted from said signal separation unit,
a second circuit unit for inputting said second frequency band signal outputted from said signal separation unit, and
a third circuit unit for limiting passing of a signal whose frequency band is lower than said second frequency band, and permitting passing of said second frequency band signal and a signal whose frequency band is higher than said second frequency band.

12. An ESD protection circuit, comprising:
a diplexer connected to an antenna terminal and branching signals whose pass bands are different,
a parallel-connected inductor provided on a low-frequency side branched by said diplexer, and becoming a first protection circuit, and
a series-connected capacitor provided at a subsequent stage to said inductor, and becoming a second protection circuit.

13. The ESD protection circuit according to claim 12, further comprising:
a high-frequency switch circuit for switching said signal on said low-frequency side branched by said diplexer,
a low-pass filter connected between said high-frequency switch circuit and a transmission terminal, and
a parallel-connected inductor provided between said high-frequency switch circuit and said low-pass filter, and becoming a third protection circuit.

14. The ESD protection circuit according to claim 13, further comprising:
a parallel-connected inductor and a parallel-connected capacitor provided between said high-frequency switch circuit and a SAW filter, and becoming a fourth protection circuit.

15. The ESD protection circuit according to claim 14, comprising:
said parallel-connected inductor and said parallel-connected capacitor provided between said high-frequency switch circuit and said SAW filter, and becoming said fourth protection circuit,
said ESD protection circuit, further comprising:
a series-connected capacitor provided between said high-frequency switch circuit and said SAW filter, and becoming a fifth protection circuit.

16. The ESD protection circuit according to claim 12, wherein said high-frequency switch circuit is configured with a PIN diode.

17. The ESD protection circuit according to claim 12, wherein said high-frequency switch circuit is configured with a semiconductor switch.

18. The ESD protection circuit according to claim 12, wherein at least part of said inductor and said capacitor which configure said ESD protection circuit is built-in inside a dielectric substrate.

19. An antenna duplexer on which said ESD protection circuit according to claim 12 is mounted.

20. An information processing apparatus which comprises said signal circuit according to claim 1, said signal circuit being an ESD protection circuit.
